(19) United States
(12) Patent Application Publication
(10) Pub. No.: US 2026/0152388 A1
(43) Pub. Date: Jun. 4, 2026

(54) PRESSURE SENSOR MANUFACTURING METHOD

(71) Applicant: Japan Display Inc., Tokyo (JP)

(72) Inventors: Shinichiro OKA, Tokyo (JP); Chiharu KABURAGI, Tokyo (JP); Yoshinori AOKI, Tokyo (JP); Fumiyuki OOKUNI, Tokyo (JP); Takuo KAITOH, Tokyo (JP); Yuta HAGA, Tokyo (JP)

(21) Appl. No.: 19/406,109

(22) Filed: Dec. 2, 2025

(30) Foreign Application Priority Data
Dec. 3, 2024 (JP) 2024-209875

(51) Int. Cl. B81C 1/00; G01L 1/18

(52) U.S. Cl. CPC B81C 1/00246; G01L 1/18; B81B 2201/0264; B81C 2201/0185

(57) ABSTRACT

According to one embodiment, a pressure sensor manufacturing method includes forming a transistor above a support substrate, forming an insulating layer covering the transistor, forming a detection electrode connected to the transistor, and a common electrode, on the insulating layer, and forming a pressure-sensitive layer by applying a pressure-sensitive layer material onto the detection electrode by a printing method.

### CROSS-REFERENCE TO RELATED APPLICATIONS

This application is based upon and claims the benefit of priority from Japanese Patent Application No. 2024-209875, filed Dec. 3, 2024, the entire contents of which are incorporated herein by reference.

### FIELD

Embodiments described herein relate generally to a pressure sensor manufacturing method.

### BACKGROUND

Various pressure sensors capable of detecting pressure distribution have been proposed. For such pressure sensors, manufacturing methods that can suppress reduction in reliability are desired.

### BRIEF DESCRIPTION OF THE DRAWINGS

FIG. 1 is a plan view showing a configuration example of a pressure sensor of the first embodiment.

FIG. 2 is a plan view showing the configuration example of the pressure sensor shown in FIG. 1.

FIG. 3 is a schematic cross-sectional view showing the pressure sensor along III-III line in FIG. 2.

FIG. 4 is a circuit diagram showing an example of the circuit configuration of the pressure sensor shown in FIG. 1.

FIG. 5 is a cross-sectional view illustrating a state in which an input surface of the pressure sensor shown in FIG. 1 is pressed.

FIG. 6 is a diagram illustrating an example of a method of manufacturing the pressure sensor shown in FIG. 2.

FIG. 7 is a diagram illustrating an example of a method of manufacturing the pressure sensor shown in FIG. 2.

FIG. 8 is a diagram illustrating an example of a method of manufacturing the pressure sensor shown in FIG. 2.

FIG. 9 is a plan view showing a configuration example of a pressure sensor of a second embodiment.

FIG. 10 is a schematic cross-sectional view showing the pressure sensor along X-X line in FIG. 9.

FIG. 11 is a diagram illustrating an example of a method of manufacturing the pressure sensor shown in FIG. 9.

FIG. 12 is a diagram illustrating an example of a method of manufacturing the pressure sensor shown in FIG. 9.

FIG. 13 is a diagram illustrating an example of a method of manufacturing the pressure sensor shown in FIG. 9.

### DETAILED DESCRIPTION

In general, according to one embodiment, a pressure sensor manufacturing method includes forming a transistor above a support substrate, forming an insulating layer covering the transistor, forming a detection electrode connected to the transistor, and a common electrode, on the insulating layer, and forming a pressure-sensitive layer by applying a pressure-sensitive layer material onto the detection electrode by a printing method.

According to another embodiment, a pressure sensor manufacturing method includes forming a transistor above a support substrate, forming an insulating layer covering the transistor, forming a detection electrode connected to the transistor on the insulating layer, forming a pressure-sensitive layer by applying a pressure-sensitive layer material onto the detection electrode by a printing method, and forming a common electrode on the pressure-sensitive layer.

According to this configuration, a pressure sensor manufacturing method capable of suppressing reduction in reliability can be provided.

Embodiments will be described hereinafter with reference to the accompanying drawings. The disclosure is merely an example, and proper changes within the spirit of the invention, which are easily conceivable by a person of ordinary skill in the art, are included in the scope of the invention as a matter of course. In addition, in some cases, in order to make the description clearer, the widths, thicknesses, shapes and the like, of the respective parts are schematically illustrated in the drawings, compared to the actual modes. However, the schematic illustration is merely an example, and adds no restriction to the interpretation of the invention. In addition, in the specification and drawings, structural elements which function in the same or a similar manner to those described in connection with preceding drawings are denoted by like reference numbers, detailed description thereof being omitted unless necessary.

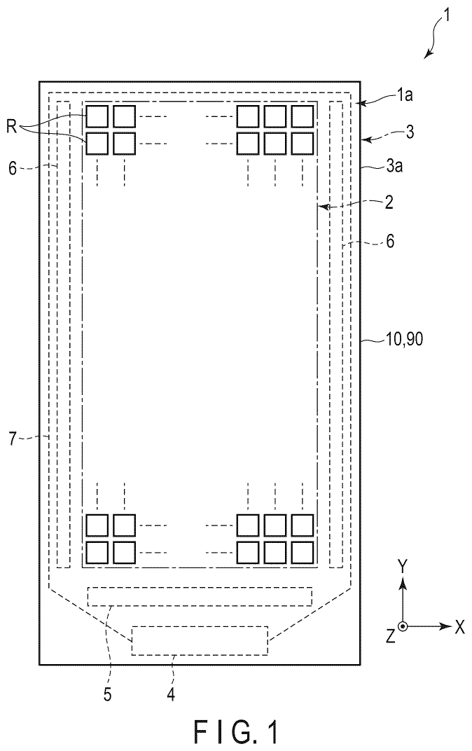

FIG. 1 is a plan view showing a configuration example of a pressure sensor 1 of the present embodiment. In one example, the first direction X, the second direction Y, and the third direction Z are orthogonal to each other, but may intersect at an angle other than ninety degrees. The first direction X and the second direction Y correspond to directions parallel to the surface of a substrate which constitutes the pressure sensor 1, and the third direction Z corresponds to a thickness direction of the pressure sensor 1. As described herein, a direction from the substrate 10 toward a protective layer 90 is referred to as an upward direction (or, more simply, upwardly), and a direction from the protective layer 90 toward the substrate 10 is referred to as a downward direction (or, more simply, downwardly). According to “a second member above/on a first member” and “a second member below/under a first member”, the second member may be in contact with the first member or may be separated from the first member. In addition, an observation position at which the pressure sensor 1 is to be observed is assumed to be located on the tip side of the arrow indicating the third direction Z, and viewing from the observation position toward an X-Y plane defined by the first direction X and the second direction Y is referred to as plan view.

In the present embodiment, the pressure sensor 1 is a pressure distribution sensor. The pressure sensor 1 comprises a substrate 10. The substrate 10 is formed in a flat plate shape parallel to the X-Y plane. In planar view, the substrate 10 has, for example, a rectangular shape.

In the example shown in FIG. 1, the pressure sensor 1 comprises a protective layer 90. The protective layer 90 is formed in a flat plate shape parallel to the X-Y plane. The substrate 10 and the protective layer 90 overlap in planar view.

The pressure sensor 1 has an input surface 1a on one side to which pressure is applied. In the example shown in FIG. 1, the pressure sensor 1 has an input surface 1a on a side opposite to the surface of the protective layer 90, which faces the substrate 10. The pressure sensor 1 detects a pressure applied to the input surface 1a.

The input surface 1a, in plan view, includes a detection unit 2 that detects the pressure and a frame-like non-detection unit 3 surrounding the detection unit 2. The detection unit 2 includes a plurality of detection areas R. In the example shown in FIG. 1, the plurality of detection areas R are arranged in parallel in the first direction X and the second direction Y.

The pressure sensor 1 further includes a connection unit 4, a gate line drive circuit 5, a signal line selection circuit 6, a common line 7, and the like. In addition, the pressure sensor 1 includes a gate line 8 and a signal line 9 (not shown). The connection unit 4, the gate line drive circuit 5, the signal line selection circuit 6, the common line 7, the gate line 8, and the signal line 9 are provided between the substrate 10 and the protective layer 90. Each of the connection unit 4, the gate line drive circuit 5, the signal line selection circuit 6, and the common line 7 overlaps with the non-detection unit 3 in plan view.

The connection unit 4 is provided to connect the pressure sensor 1 to a drive integrated circuit (IC) (not shown) provided outside the pressure sensor 1. Incidentally, the drive IC may be mounted as a Chip On Film (COF) on a flexible printed circuit board or rigid board connected to the connection unit 4. Alternatively, the drive IC may be mounted as a Chip On Glass (COG) in an area which overlaps with the non-detection unit 3 of the substrate 10.

The gate line drive circuit 5 is a circuit that drives a plurality of gate lines 8, based on various control signals from the drive IC. The gate line drive circuit 5 sequentially or simultaneously selects a plurality of gate lines 8 and supplies gate drive signals to the selected gate lines 8.

The signal line selection circuit 6 is a switch circuit that sequentially or simultaneously selects a plurality of signal lines 9. The signal line selection circuit 6 is, for example, a multiplexer. The signal line selection circuit 6 connects the selected signal lines 9 with the drive IC, based on selection signals supplied from the drive IC.

The common line 7 is a wire for supplying a predetermined voltage to the common electrode and is provided along an outer edge 3a of the non-detection unit 3. The common line 7 is connected to the drive IC via the connection unit 4 and receives a constant voltage from the drive IC.

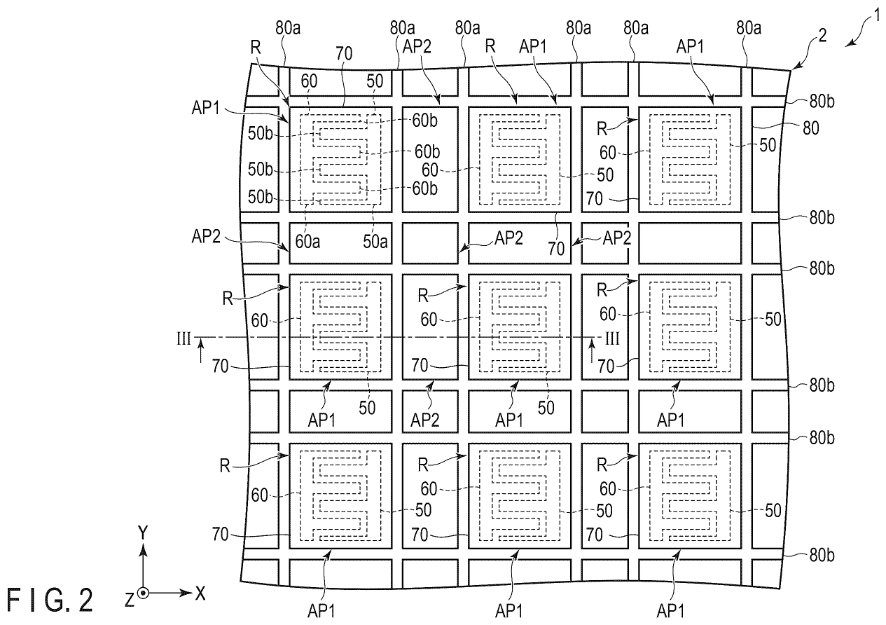

FIG. 2 is a plan view showing a configuration example of the pressure sensor 1 shown in FIG. 1. The detection unit 2 of the pressure sensor 1 will be described here. In FIG. 2, the protective layer 90 is omitted.

The pressure sensor 1 includes a plurality of detection areas R and a partition 80. In the example shown in FIG. 2, the plurality of detection areas R are arranged in parallel in the first direction X and the second direction Y.

Each of the plurality of detection areas R includes a detection electrode 50, a common electrode 60, a pressure-sensitive layer 70, and a transistor 30 (not shown). The detection electrode 50 comprises a single electrode 50a extending in the second direction Y and a plurality of electrodes 50b extending from the electrode 50a in the first direction X. The common electrode 60 comprises a single electrode 60a extending in the second direction Y and a plurality of electrodes 60b extending from the electrode 60a in the first direction X. The electrodes 50b and 60b are provided alternately in the second direction Y. The pressure-sensitive layer 70 overlaps with the detection electrode 50 and the common electrode 60. The pressure-sensitive layer 70 has, for example, a rectangular shape.

The partition 80 is located between two pressure-sensitive layers 70 adjacent in the first direction X or the second direction Y. In the example shown in FIG. 2, the partition 80 comprises a plurality of first partitions 80a arranged in parallel in the first direction X and extending in the second direction Y, and a plurality of second partitions 80b arranged in parallel in the second direction Y and extending in the first direction X. Two first partitions 80a are provided between the pressure-sensitive layers 70 adjacent in the first direction X. Two second partitions 80b are provided between the pressure-sensitive layers 70 adjacent in the second direction Y. Intersecting first partitions 80a and second partitions 80b are interconnected. The partition 80 is thereby formed in a grating shape that surrounds each of the plurality of pressure-sensitive layers 70 as a whole.

In the example shown in FIG. 2, the partition 80 includes a plurality of apertures AP1 that overlap with the pressure-sensitive layers 70. In addition, the partition 80 further includes a plurality of apertures AP2 that do not overlap with the pressure-sensitive layers 70. In the example shown in FIG. 2, the apertures AP1 have a rectangular shape of the same size as the pressure-sensitive layers 70. In the partition 80, a column where the apertures AP1 and AP2 are alternately provided in the first direction X, and a column where a plurality of apertures AP2 are repeatedly provided in the first direction X are formed. These columns are alternately arranged in parallel in the second direction Y. Furthermore, in the partition 80, a column where the apertures AP1 and AP2 are alternately arranged in the second direction Y, and a column where a plurality of apertures AP2 are repeatedly provided in the second direction Y are formed. These columns are alternately arranged in parallel in the first direction X.

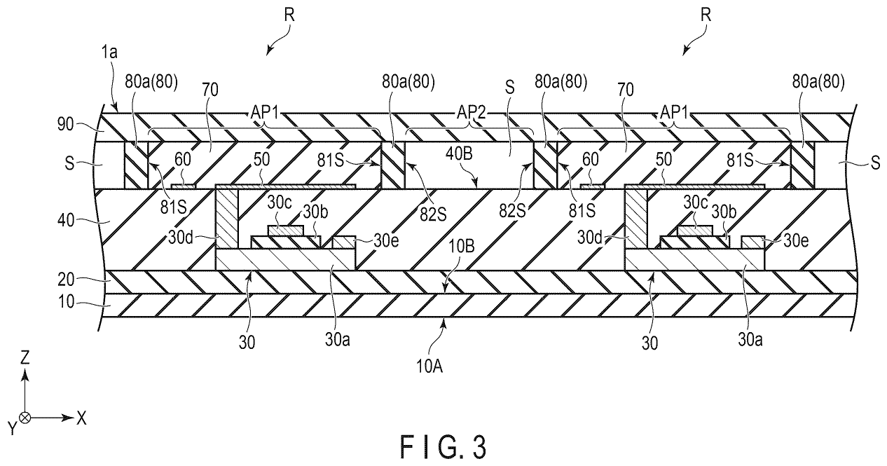

FIG. 3 is a schematic cross-sectional view showing the pressure sensor 1 along III-III line in FIG. 2.

The pressure sensor 1 comprises a substrate 10, an insulating layer 20, a plurality of transistors 30, an insulating layer 40, a plurality of detection electrodes 50, a plurality of common electrodes 60, a plurality of pressure-sensitive layers 70, a partition 80, and a protective layer 90. The pressure sensor 1 further comprises a connection unit 4, a gate line drive circuit 5, a signal line selection circuit 6, a common line 7, and the like, which are shown in FIG. 1. The pressure sensor 1 further comprises a gate line 8 and a signal line 9, which are not shown in the figure.

The substrate 10 comprises a main surface (lower surface) 10A and a main surface (upper surface) 10B on a side opposite to the main surface 10A. The main surfaces 10A and 10B are the surfaces substantially parallel to the X-Y plane. The insulating layer 20 covers the main surface 10B. Each of the plurality of transistors 30 is provided on the insulating layer 20 for each detection area R.

The transistor 30 comprises a semiconductor layer 30a, a gate insulating film 30b, a gate electrode 30c, a drain electrode 30d, and a source electrode 30e. The semiconductor layer 30a is provided on the insulating layer 20. The gate insulating film 30b is provided on the semiconductor layer 30a. The gate electrode 30c is provided on the gate insulating film 30b. The drain electrode 30d is provided on the semiconductor layer 30a. The drain electrode 30d is electrically connected to the gate line 8 (not shown). The source electrode 30e is provided on the semiconductor layer 30a. The source electrode 30e is electrically connected to the signal line 9 (not shown).

The insulating layer 40 covers the insulating layer 20 and each of the plurality of transistors 30. The insulating layer 40 has a surface 40B facing the protective layer 90. The surface 40B is planarized. Although not shown, the connection unit 4, the gate line drive circuit 5, the signal line selection circuit 6, the common line 7, the gate line 8, and the signal line 9 are provided between the main surface 10B and the surface 40B.

Each of the plurality of detection electrodes 50 is provided on the surface 40B for each detection area R. The detection electrode 50 is electrically connected to the drain electrode 30d and is also electrically connected to the transistor 30. Each of the plurality of common electrodes 60 is provided on the surface 40B for each detection area R. In the detection area R, the detection electrode 50 and the common electrode 60 are adjacent to each other via the pressure-sensitive layer 70. The detection electrode 50 and the common electrode 60 are provided on the same plane. In other words, the pressure sensor 1 comprises so-called parallel-type electrodes.

Each of the plurality of pressure-sensitive layers 70 is formed for each detection area R. The pressure-sensitive layer 70 covers the detection electrode 50 and the common electrode 60. The pressure-sensitive layer 70 is in contact with the surface 40B between the detection electrode 50 and the common electrode 60. The pressure-sensitive layer 70 is in contact with the surface 40B between the detection electrode 50 and the partition 80 and between the common electrode 60 and the partition 80.

The partition 80 is provided on the surface 40B. In the example shown in FIG. 3, two first partitions 80a are provided on the surface 40B between two adjacent pressure-sensitive layers 70. Each of the first partitions 80a has a side surface 81S facing the pressure-sensitive layer 70 and a side surface 82S on a side opposite to the side surface 81S. The side surface 81S is in contact with the pressure-sensitive layer 70. The side surface 81S faces the side surface 81S of the other first partition 80a through the pressure-sensitive layer 70. An aperture AP1 is formed between the side surfaces 81S that face each other. The detection electrode 50, the common electrode 60, and the pressure-sensitive layer 70 are provided in aperture AP1.

The side surface 82S faces the side surface 82S of the other first partition 80a through a gap S. An aperture AP2 is formed between the side surfaces 82S that face each other. The surface 40B is exposed at the aperture AP2.

The protective layer 90 covers each of the plurality of pressure-sensitive layers 70. In the example shown in FIG. 3, the protective layer 90 covers each of the plurality of pressure-sensitive layers 70 and the partition 80, and covers the entire surface of the pressure sensor 1. The protective layer 90 has an input surface 1a on a side opposite to the surface which faces the substrate 10.

The substrate 10 is, for example, a resin layer formed of resin such as polyimide (PI). The insulating layers 20 and 40 are inorganic or organic insulating films. The insulating layer 20 is formed of, for example, a polyimide-based resin. The partition 80 is formed of, for example, an insulating material such as an acrylic-based resin or an epoxy-based resin. The protective layer 90 is a substrate having both insulation and flexibility. The protective layer 90 is, for example, a substrate or film formed of a resin such as polycarbonate (PC) or polyethylene terephthalate (PET), an inorganic film formed of an inorganic material such as SiO or SiN, or a decorative film.

The detection electrode 50 and the common electrode 60 are, for example, electrodes formed of metal materials such as molybdenum-tungsten alloy (MoW), aluminum-titanium alloy (AlTi), and copper, silver nano-ink, or conductive polymers such as poly(3,4-ethylenedioxythiophene)/poly(styrenesulfonate) (PEDOT/PSS).

The material of the pressure-sensitive layer 70 is not particularly limited as long as it is a material whose resistance value changes with change in pressure, and the layer is formed of, for example, a material containing a conductive material. The pressure-sensitive layer 70 is formed of, for example, carbon paste or silver nano-ink. The pressure-sensitive layer 70 may further contain spacer materials for increasing the change in resistance value in response to the change in pressure. The pressure sensor 1 may include two or more types of pressure-sensitive layers each exhibiting a different change in resistance value in response to the change in pressure, as the pressure-sensitive layer 70. In addition, the pressure-sensitive layer 70 may be composed of two or more types of pressure-sensitive layers that are different in changes in resistance value in response to the change in pressure.

Such a pressure-sensitive layer 70 formed of a material containing the conductive material has a high resistance value when no pressure is applied, since the area where the conductive materials are in contact with each other is small. When pressure is applied to the detection unit 2, the pressure-sensitive layer 70 is deformed and the area where the conductive materials contained in the pressure-sensitive layer 70 are in contact with each other is increased, causing the resistance value of the pressure-sensitive layer 70 to decrease. If pressure is further applied to the detection unit 2 and the amount of deformation of the pressure-sensitive layer 70 is increased, the area where the conductive materials are in contact with each other is further increased, causing the resistance value of the pressure-sensitive layer 70 to further decrease. Thus, in the pressure-sensitive layer 70 formed of a material containing the conductive materials, its resistance value changes in response to the change in pressure.

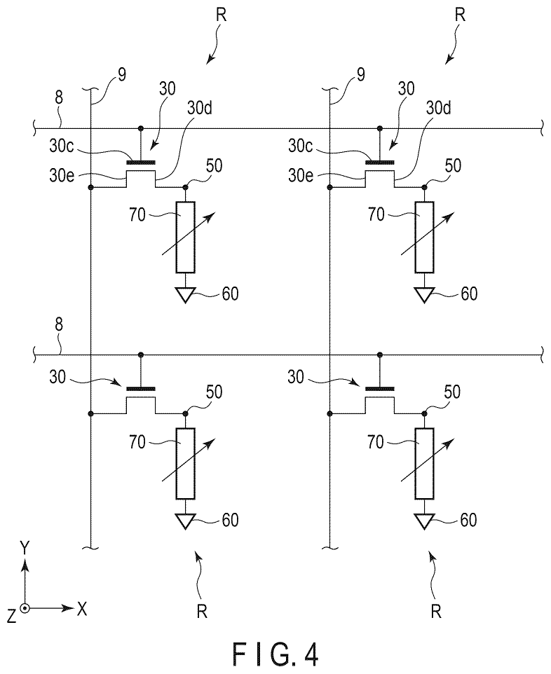

FIG. 4 is a circuit diagram showing an example of the circuit configuration of the pressure sensor 1 shown in FIG. 1. As shown in FIG. 4, the gate electrodes 30c are electrically connected to the gate lines 8. In addition, the source electrodes 30e are electrically connected to the signal lines 9. In other words, each of the transistors 30 is electrically connected to the gate line 8 and the signal line 9.

The gate line 8 extends in the first direction X and is electrically connected to each of the transistors 30 of the plurality of detection areas R arranged in the first direction X. The signal line 9 extends in the second direction Y, intersects with the gate line 8, and is electrically connected to each of the transistors 30 of the plurality of detection areas R arranged in the second direction Y. The detection electrode 50 is electrically connected to the drain electrode 30d.

When the gate line 8 is scanned, the detection electrode 50 and the signal line 9 are electrically connected. As a result, the value of the current flowing between the detection electrode 50 and the common electrode 60 can be obtained via the signal line 9. The pressure applied to the input surface 1a can be detected from the obtained current value.

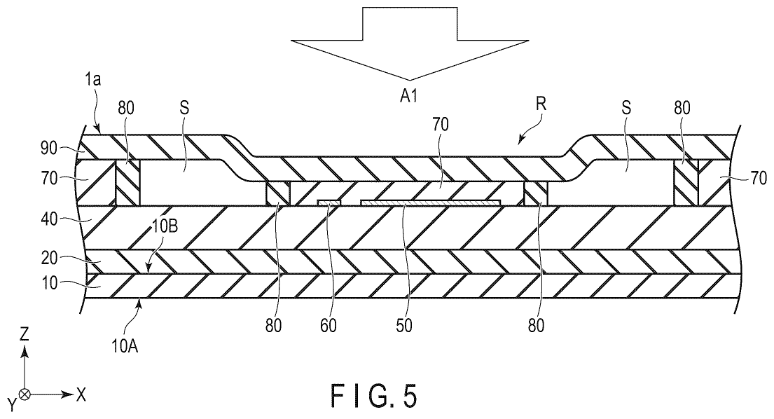

FIG. 5 is a cross-sectional view illustrating a state in which the input surface 1a of the pressure sensor 1 is pressed. The transistors 30 are omitted in FIG. 5.

In the detection area R, the detection electrode 50 and the common electrode 60 are adjacent to each other via the pressure-sensitive layer 70. When the input surface 1a of the pressure sensor 1 is not pressed, the pressure-sensitive layer 70 has a high resistance value. Therefore, when the input surface 1a is not pressed, the detection electrode 50 and the common electrode 60 are not electrically connected to each other.

As shown in FIG. 5, when the input surface 1a is pressed by, for example a hand, a finger, or the like, pressure is applied to the input surface 1a in the direction from the protective layer 90 toward the substrate 10, i.e., A1 direction. At this time, in the detection area R, the pressure-sensitive layer 70 is compressed in the A1 direction, the area where the conductive materials contained in the pressure-sensitive layer 70 are in contact with each other, and the resistance value of the pressure-sensitive layer 70 decreases. For this reason, a current flows between the detection electrode 50 and the common electrode 60 via the pressure-sensitive layer 70.

When the pressure applied to the input surface 1a in the A1 direction increases, the pressure-sensitive layer 70 is further compressed in the A1 direction, and the area where the conductive materials are in contact with each other further increases. Thus, the resistance value of the pressure-sensitive layer 70 further decreases and the current flowing between the detection electrode 50 and the common electrode 60 via the pressure-sensitive layer 70 increases. In other words, as the pressure applied to the input surface 1a increases, the value of the current flowing between the detection electrode 50 and the common electrode 60 via the pressure-sensitive layer 70 (current value) increases. By detecting such changes in current value, changes in the pressure applied to the input surface 1a can be detected.

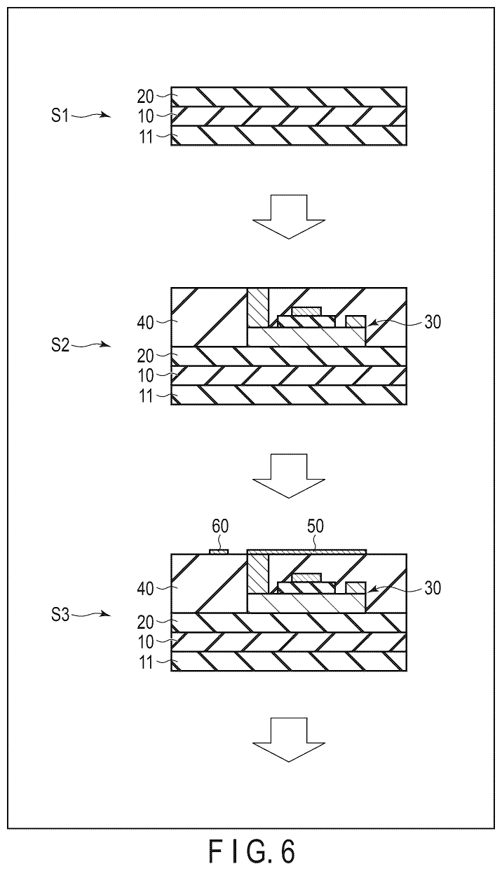

Next, a method of manufacturing the pressure sensor 1 according to the first embodiment will be described. FIG. 6 to FIG. 8 are diagrams illustrating an example of the method of manufacturing the pressure sensor 1. FIG. 6 to FIG. 8 show a cross-section of the detection unit 2 of the pressure sensor 1.

In manufacturing the pressure sensor 1, first, the substrate 10 is formed on the support substrate 11, and the insulating layer 20 is formed on the substrate 10 (process S1 in FIG. 6). The support substrate 11 is formed of, for example, glass. After the process S1, the transistor 30 is formed on the insulating layer 20, and the insulating layer 40 covering the transistor 30 is formed (process S2 in FIG. 6). After the process S2, the detection electrode 50 and the common electrode 60 are formed on the insulating layer 40 (process S3 in FIG. 6). The detection electrode 50 and the common electrode 60 are formed by, for example, patterning a metal film formed on the insulating layer 40 by sputtering or the like. The detection electrode 50 and common electrode 60 may also be formed by, for example, applying silver nano-ink or conductive polymer onto the insulating layer 40 by a printing method or the like.

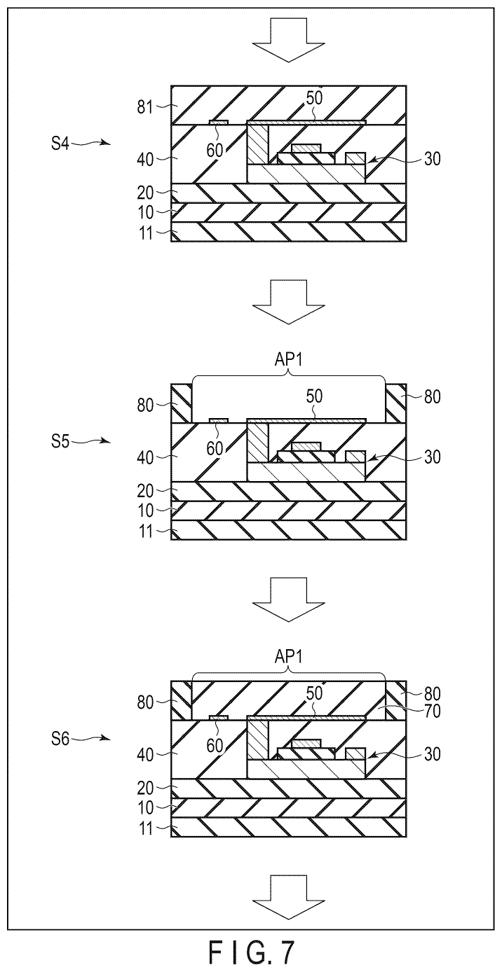

After the process S3, an insulating layer 81 which forms the basis of the partition 80 is formed on the insulating layer 40 (process S4 in FIG. 7). The insulating layer 81 is formed of, for example, an insulating material such as an acrylic resin or an epoxy resin. The insulating layer 81 covers the detection electrode 50 and the common electrode 60. After the process S4, the aperture AP1 is formed in the insulating layer 81, and the partition 80 is formed (process S5 in FIG. 7). The partition 80 is formed by, for example, patterning the insulating layer 81 using photolithography or the like. Alternatively, the partition 80 may also be formed by applying a partition material onto the insulating layer 40 using a printing method such as screen printing, flexographic printing, or ink jet printing.

After the process S5, the pressure-sensitive layer 70 is formed in the aperture AP1 (process S6 in FIG. 7). The pressure-sensitive layer 70 is formed by applying a pressure-sensitive layer material onto the detection electrode 50 using, for example, a printing method such as screen printing, flexographic printing, or ink jet printing. The pressure-sensitive layer material is a material containing a conductive material such as silver nano-ink or carbon paste. For example, the pressure-sensitive layer material is applied inside an area surrounded by the partition 80 in plan view, forming the pressure-sensitive layer 70 inside the area. As a result, applying the pressure-sensitive layer material onto an undesired location and the spread of the pressure-sensitive layer material to be cured are suppressed.

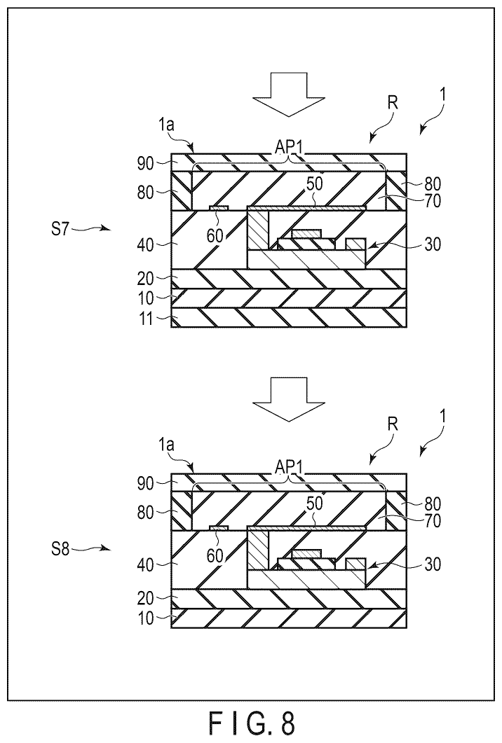

After the process S6, the protective layer 90 is formed on the pressure-sensitive layer 70 and the partition 80, completing the pressure sensor 1 (process S7 in FIG. 8). The protective layer 90 may be formed by, for example, applying a film-like protective layer 90 onto the pressure-sensitive layer 70 and the partition 80. Alternatively, the protective layer 90 may also be formed by CVD, printing, or the like. After the process S7, the support substrate 11 may be peeled off and removed from the substrate 10 by laser lift-off or the like (process S8 in FIG. 8).

In manufacturing the pressure sensor, the pressure-sensitive layer may be formed by providing a sheet-like pressure-sensitive layer on the detection electrode. In this case, the pressure-sensitive layer may be displaced from a desired location, reducing the reliability of the pressure sensor. Furthermore, the method for fixing the pressure-sensitive layer on the detection electrode may cause a problem.

In the present embodiment, the pressure-sensitive layer is formed by applying the pressure-sensitive layer material onto the detection electrode by a printing method. For this reason, displacement of the pressure-sensitive layer from a desired location can be suppressed, and the pressure-sensitive layer does not need to be fixed onto the detection electrode by the other methods.

Therefore, according to the present embodiment, a method of manufacturing a pressure sensor capable of suppressing the reduction in reliability can be provided.

### SECOND EMBODIMENT

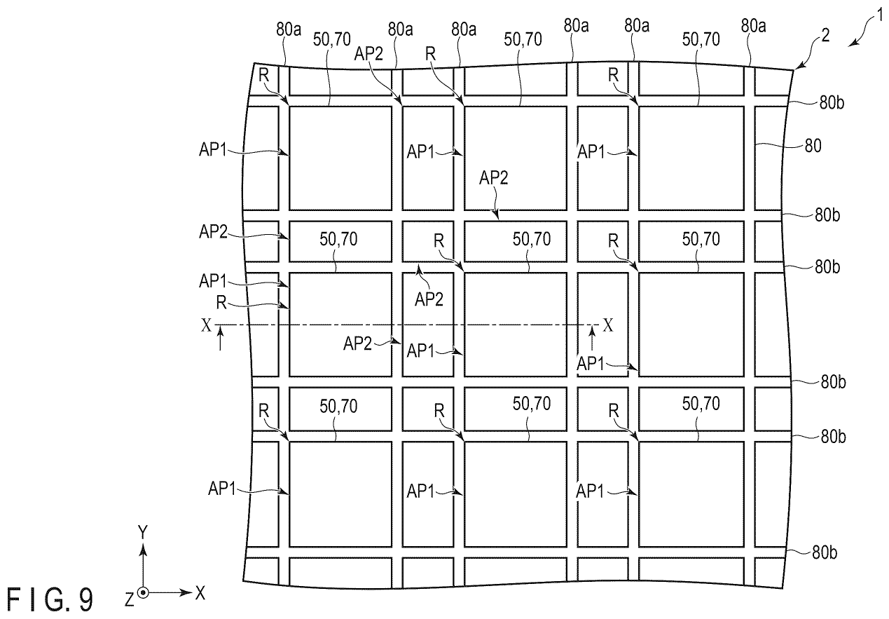

FIG. 9 is a plan view showing a configuration example of a pressure sensor 1 of a second embodiment. Description of the same configuration as the above-described first embodiment will be omitted with reference to the above description. The detection unit 2 of the pressure sensor 1 will be described here. In FIG. 9, a protective layer 90 is omitted.

The pressure sensor 1 comprises a plurality of detection areas R, a partition 80, and a common electrode 60 (not shown). In the example shown in FIG. 6, the plurality of detection areas R are arranged in parallel in the first direction X and the second direction Y.

Each of the plurality of detection areas R includes a detection electrode 50, a pressure-sensitive layer 70, and a transistor 30 (not shown). The pressure-sensitive layer 70 overlaps with the detection electrode 50. In the example shown in FIG. 9, the pressure-sensitive layer 70 has a rectangular shape of the same size as the detection electrode 50, but the pressure-sensitive layer 70 may also have an area smaller than the detection electrode 50.

In the example shown in FIG. 9, the partition 80 comprises a plurality of first partitions 80a arranged in parallel in the first direction X and extending in the second direction Y, and a plurality of second partitions 80b arranged in parallel in the second direction Y and extending in the first direction X. Two first partitions 80a are provided between the pressure-sensitive layers 70 adjacent in the first direction X. Two second partitions 80b are provided between the pressure-sensitive layers 70 adjacent in the second direction Y. Intersecting first partitions 80a and second partitions 80b are interconnected. The partition 80 is thereby formed in a grating shape that surrounds each of the plurality of pressure-sensitive layers 70 as a whole. The partition 80 includes a plurality of apertures AP1 that overlap with the pressure-sensitive layers 70. In addition, the partition 80 further includes a plurality of apertures AP2 that do not overlap with the pressure-sensitive layers 70. In the example shown in FIG. 9, the apertures AP1 have a rectangular shape of the same size as the pressure-sensitive layers 70.

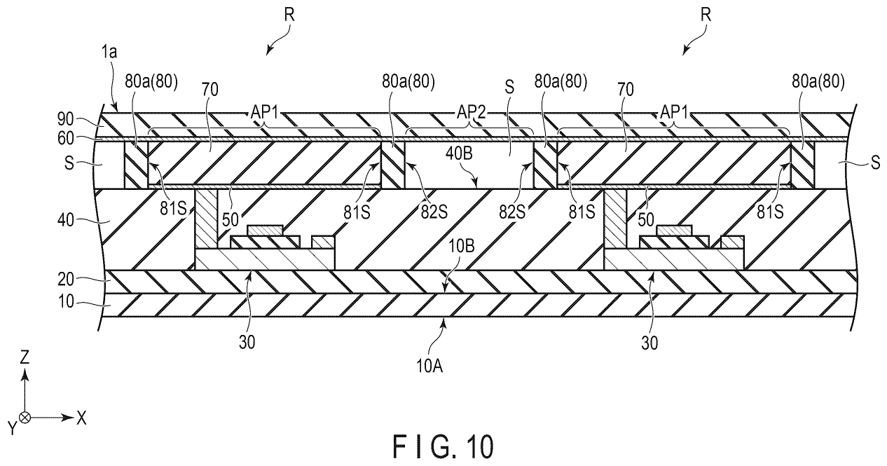

FIG. 10 is a schematic cross-sectional view showing the pressure sensor 1 along X-X line in FIG. 9. Description of the same configuration as the above-described first embodiment will be omitted with reference to the above description.

The pressure sensor 1 comprises a substrate 10, an insulating layer 20, a plurality of transistors 30, an insulating layer 40, a plurality of detection electrodes 50, a common electrode 60, a plurality of pressure-sensitive layers 70, a partition 80, and a protective layer 90.

Each of the plurality of detection electrodes 50 is provided on the surface 40B for each detection area R. Each of the plurality of pressure-sensitive layers 70 is formed for each detection area R. The pressure-sensitive layers 70 are provided on the detection electrodes 50. In the example shown in FIG. 10, the pressure-sensitive layers 70 cover the detection electrodes 50.

The partition 80 is provided on the surface 40B. In the example shown in FIG. 10, two first partitions 80a are provided on the surface 40B between two adjacent pressure-sensitive layers 70. Each of the first partitions 80a has a side surface 81S facing the pressure-sensitive layer 70 and a side surface 82S on a side opposite to the side surface 81S. The side surface 81S faces the side surface 81S of the other first partition 80a through the pressure-sensitive layer 70. An aperture AP1 is formed between the side surfaces 81S that face each other. The detection electrode 50 and the pressure-sensitive layer 70 are provided in aperture AP1.

The common electrode 60 covers each of the plurality of pressure-sensitive layers 70. In the example shown in FIG. 10, the common electrode 60 covers each of the plurality of pressure-sensitive layers 70 and the partition 80, and covers the entire surface of the pressure sensor 1. The common electrode 60 faces each of the plurality of detection electrodes 50 in the third direction Z via the pressure-sensitive layers 70.

The protective layer 90 covers the common electrode 60. The protective layer 90 has an input surface 1a on a side opposite to the surface which faces the substrate 10. The common electrode 60 is, for example, a metal film formed on the surface opposite to the input surface 1a of the protective layer 90. Incidentally, the pressure sensor 1 may not comprise the protective layer 90 and, in this case, the surface opposite to the surface of the common electrode 60, which faces the substrate 10, is the input surface 1a.

Thus, in the pressure sensor 1 according to the second embodiment, each of the plurality of detection electrodes 50 and the common electrode 60 are provided to face each other. In other words, the pressure sensor 1 of the second embodiment comprises so-called opposing electrodes.

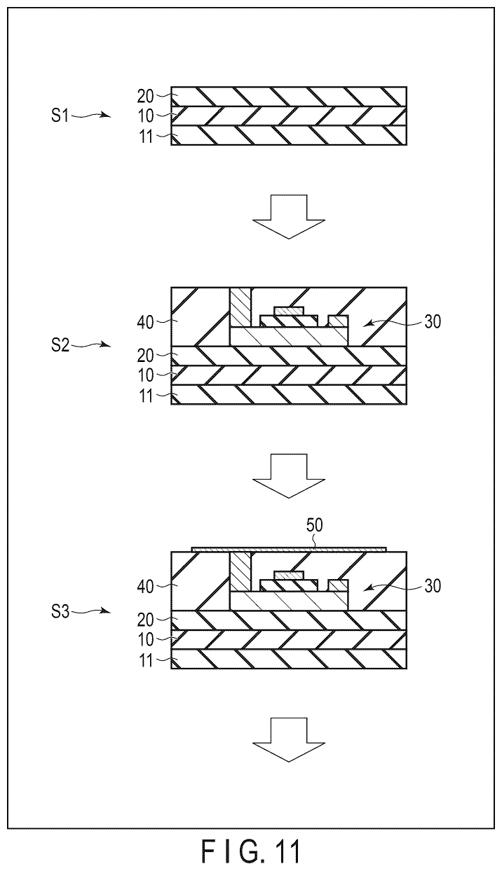

Next, a method of manufacturing the pressure sensor 1 according to the second embodiment will be described. Description of the same configuration as the method of manufacturing the pressure sensor 1 according to the above-described first embodiment will be omitted with reference to the above description. FIG. 11 to FIG. 13 are diagrams illustrating an example of the method of manufacturing the pressure sensor 1. FIG. 11 to FIG. 13 show a cross-section of the detection unit 2 of the pressure sensor 1.

In manufacturing the pressure sensor 1, first, the substrate 10 is formed on the support substrate 11, and the insulating layer 20 is formed on the substrate 10 (process S1 in FIG. 11). After the process S1, the transistor 30 is formed on the insulating layer 20, and the insulating layer 40 covering the transistor 30 is formed (process S2 in FIG. 11). After the process S2, the detection electrode 50 is formed on the insulating layer 40 (process S3 in FIG. 11). The detection electrode 50 is formed by, for example, patterning a metal film formed on the insulating layer 40 by sputtering or the like. The detection electrode 50 may also be formed by, for example, applying silver nano-ink or conductive polymer onto the insulating layer 40 by a printing method or the like.

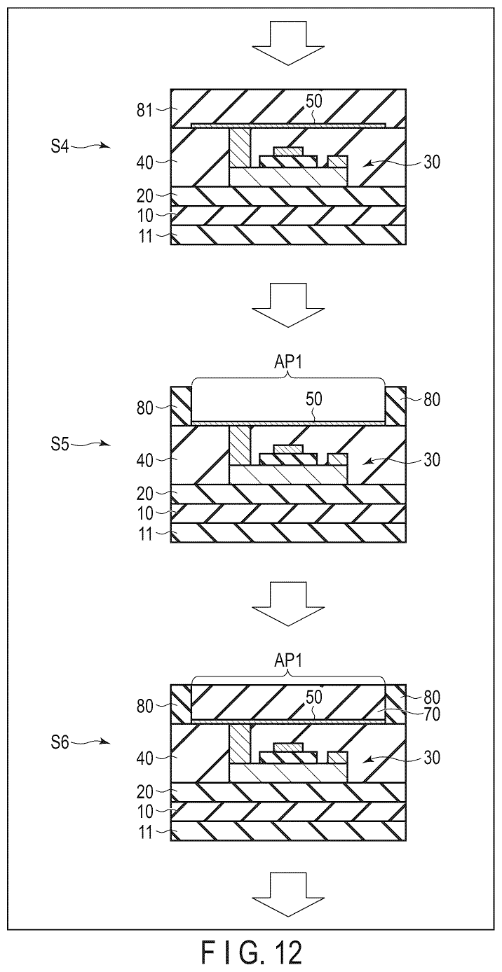

After the process S3, an insulating layer 81 which forms the basis of the partition 80 is formed on the insulating layer 40 (process S4 in FIG. 12). The insulating layer 81 covers the detection electrode 50. After the process S4, the aperture AP1 is formed in the insulating layer 81, and the partition 80 is formed (process S5 in FIG. 12).

After the process S5, the pressure-sensitive layer 70 is formed in the aperture AP1 (process S6 in FIG. 12). The pressure-sensitive layer 70 is formed by applying a pressure-sensitive layer material onto the detection electrode 50 using, for example, a printing method such as screen printing, flexographic printing, or ink jet printing. The pressure-sensitive layer material is a material containing a conductive material such as silver nano-ink or carbon paste. For example, the pressure-sensitive layer material is applied inside an area surrounded by the partition 80 in plan view, forming the pressure-sensitive layer 70 inside the area. As a result, applying the pressure-sensitive layer material onto an undesired location and the spread of the pressure-sensitive layer material to be cured are suppressed.

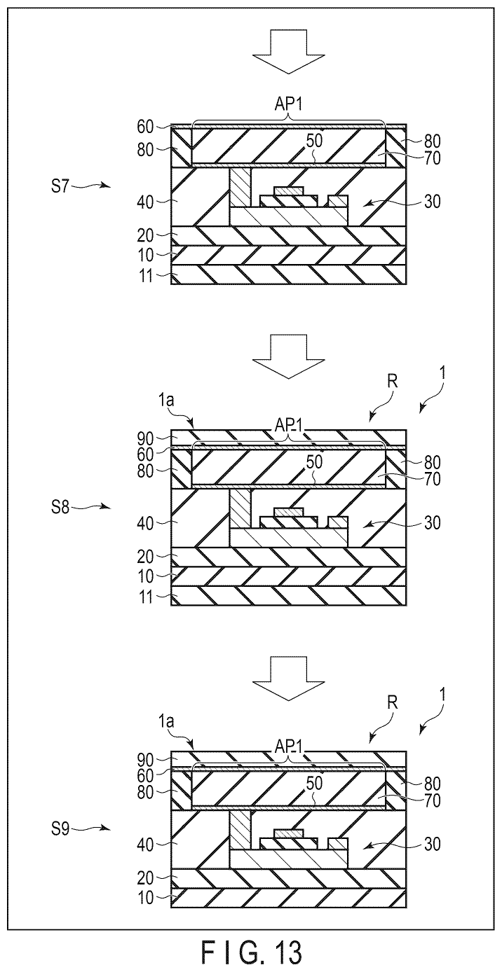

After the process S6, the common electrode 60 is formed on the pressure-sensitive layer 70 and the partition 80 (process S7 in FIG. 13). The common electrode 60 is formed by, for example, sputtering or the like. The common electrode 60 may also be formed by, for example, applying silver nano-ink or conductive polymer onto the pressure-sensitive layer 70 and the partition 80 by a printing method or the like.

After the process S7, the protective layer 90 is formed on the common electrode 60, completing the pressure sensor 1 (process S8 in FIG. 13). The protective layer 90 may be formed by, for example, applying a film-like protective layer 90 onto the common electrode 60. Alternatively, the protective layer 90 may also be formed by CVD, printing, or the like. Alternatively, the protective layer 90 and common electrode 60 may be formed simultaneously by forming a metal film on one surface of the film-like protective layer 90 to form the common electrode 60, and then applying the surface of the protective layer 90 where the common electrode 60 is formed onto the pressure-sensitive layer 70. After the process S8, the support substrate 11 may be peeled off and removed from the substrate 10 by laser lift-off or the like (process S9 in FIG. 13).

In the method of manufacturing the pressure sensor 1 according to the second embodiment as well, the effects similar to those of the first embodiment can be obtained.

As described above, according to the present embodiment, a method of manufacturing a pressure sensor, capable of suppressing the reduction in reliability, can be provided.

The present invention is not limited to the embodiments described above but the constituent elements of the invention can be modified in various manners without departing from the spirit and scope of the invention. Various aspects of the invention can also be extracted from any appropriate combination of constituent elements disclosed in the embodiments. Some constituent elements may be deleted in all of the constituent elements disclosed in the embodiments. The constituent elements described in different embodiments may be combined arbitrarily.

What is claimed is:

1. A pressure sensor manufacturing method comprising:
forming a transistor above a support substrate;
forming an insulating layer covering the transistor;
forming a detection electrode connected to the transistor, and a common electrode, on the insulating layer; and
forming a pressure-sensitive layer by applying a pressure-sensitive layer material onto the detection electrode by a printing method.

2. The pressure sensor manufacturing method of claim 1, wherein
the printing method is ink jet printing, screen printing, or flexographic printing.

3. The pressure sensor manufacturing method of claim 1, wherein
the pressure-sensitive layer material is a material containing a conductive material.

4. The pressure sensor manufacturing method of claim 3, wherein
the pressure-sensitive layer material is a material whose resistance value changes in accordance with change in pressure.

5. The pressure sensor manufacturing method of claim 3, wherein
the pressure-sensitive layer material contains silver nano-ink or carbon paste.

6. The pressure sensor manufacturing method of claim 1, further comprising:
forming a partition on the insulating layer before forming the pressure-sensitive layer; and
forming the pressure-sensitive layer in an area surrounded by the partition.

7. The pressure sensor manufacturing method of claim 6, further comprising:
forming the partition of an insulating material.

8. The pressure sensor manufacturing method of claim 7, further comprising;
forming the partition of an acrylic-based resin or an epoxy-based resin.

9. The pressure sensor manufacturing method of claim 1, further comprising:
peeling off the support substrate after forming the pressure-sensitive layer.

10. A pressure sensor manufacturing method comprising:
forming a transistor above a support substrate;
forming an insulating layer covering the transistor;
forming a detection electrode connected to the transistor on the insulating layer;
forming a pressure-sensitive layer by applying a pressure-sensitive layer material onto the detection electrode by a printing method; and
forming a common electrode on the pressure-sensitive layer.

11. The pressure sensor manufacturing method of claim 10, wherein
the printing method is ink jet printing, screen printing, or flexographic printing.

12. The pressure sensor manufacturing method of claim 10, wherein
the pressure-sensitive layer material is a material containing a conductive material.

13. The pressure sensor manufacturing method of claim 12, wherein
the pressure-sensitive layer material is a material whose resistance value changes in accordance with change in pressure.

14. The pressure sensor manufacturing method of claim 12, wherein
the pressure-sensitive layer material contains silver nano-ink or carbon paste.

15. The pressure sensor manufacturing method of claim 10, further comprising:
forming a partition on the insulating layer before forming the pressure-sensitive layer; and
forming the pressure-sensitive layer in an area surrounded by the partition.

16. The pressure sensor manufacturing method of claim 15, further comprising:
forming the partition of an insulating material.

17. The pressure sensor manufacturing method of claim 16, further comprising;
forming the partition of an acrylic-based resin or an epoxy-based resin.

18. The pressure sensor manufacturing method of claim 10, further comprising:
peeling off the support substrate after forming the pressure-sensitive layer.
